(19) United States
(12) Patent Application Publication
(10) Pub. No.: US 2025/0063863 A1
(43) Pub. Date: Feb. 20, 2025

(54) LIGHT-CONVERSION MODULE, METHOD FOR MANUFACTURING THE SAME, AND DISPLAY

(71) Applicant: LITE-ON TECHNOLOGY CORPORATION, TAIPEI CITY (TW)

(72) Inventor: YUAN-JU CHENG, Kaohsiung City (TW)

(21) Appl. No.: 18/786,613

(22) Filed: Jul. 29, 2024

Related U.S. Application Data
(60) Provisional application No. 63/532,892, filed on Aug. 15, 2023.

(30) Foreign Application Priority Data
Apr. 29, 2024 (CN) 202410524018.5

(51) Int. Cl. H01L 33/50; H01L 25/075

(52) U.S. Cl. CPC H01L 33/502; H01L 25/0753; H01L 2933/0041

(57) ABSTRACT

A light-conversion module, a method for manufacturing the light-conversion module, and a display are provided. The light-conversion module includes a pixel layer, an inorganic blocking wall structure, and a plurality of color filters. The inorganic blocking wall structure is disposed on the pixel layer and has a plurality of through holes. The plurality of color filters are respectively disposed in the plurality of through holes. An upper surface of the inorganic blocking wall structure is higher than an upper surface of each of the plurality of color filters.

### CROSS-REFERENCE TO RELATED PATENT APPLICATION

This application claims the benefit of priority to China Patent Application No. 202410524018.5, filed on Apr. 29, 2024, in the People's Republic of China. The entire content of the above identified application is incorporated herein by reference.

This application claims the benefit of priority to the U.S. Provisional Patent Application Ser. No. 63/532,892, filed on Aug. 15, 2023, which application is incorporated herein by reference in its entirety.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a light-conversion module, a method for manufacturing the light-conversion module, and a display, and more particularly to a light-conversion module having high blocking walls, a method for manufacturing the light-conversion module, and a display including the light-conversion module.

### BACKGROUND OF THE DISCLOSURE

In recent years, micro-light-emitting diodes have gradually been adopted in light-emitting modules of displays. In order to overcome the color mixing issue of the three primary colors of RGB, blocking walls are used between pixels to prevent light interference from sub-pixels of different colors.

However, existing blocking walls are made of black photoresist, which is formed through a yellow-light lithography process. Since black photoresist is not easily exposed, a height of the blocking wall is limited and cannot effectively block light interference (i.e., a crosstalk phenomenon) from adjacent sub-pixels of different colors. Therefore, how to increase the height of the blocking wall through improvements in production for overcoming the above-mentioned problems has become one of the important issues to be addressed in the relevant industry.

### SUMMARY OF THE DISCLOSURE

In response to the above-referenced technical inadequacies, the present disclosure provides a light-conversion module, a method for manufacturing the light-conversion module, and a display. A height of the inorganic blocking wall structure in the light-conversion module provides an improved blocking effect, thereby increasing a contrast of the display.

In order to solve the above-mentioned problems, one of the technical aspects adopted by the present disclosure is to provide a light-conversion module. The light-conversion module includes a pixel layer, an inorganic blocking wall structure, and a plurality of color filters. The inorganic blocking wall structure is disposed on the pixel layer and has a plurality of through holes. The plurality of color filters are respectively disposed in the plurality of through holes. An upper surface of the inorganic blocking wall structure is higher than an upper surface of each of the plurality of color filters.

In order to solve the above-mentioned problems, another one of the technical aspects adopted by the present disclosure is to provide a method for manufacturing a light-conversion module. The method includes steps as follows: forming second portions of each of a plurality of through holes in an inorganic blocking wall structure on a substrate, in which the inorganic blocking wall structure has the plurality of through holes; providing a plurality of color filters at the second portions of the plurality of through holes, respectively; providing first color conversion parts, second color conversion parts, and light-permeable parts on the color filters, so as to form a pixel layer; in which the first color conversion parts, the second color conversion parts, and the light-permeable parts correspond to a plurality of first sub-pixel regions, a plurality of second sub-pixel regions, and a plurality of third sub-pixel regions of the pixel layer, respectively; and performing a hole-forming process for the substrate to form a first portion for each of the through holes, and the first portions correspond to the second portions to form the through holes.

In order to solve the above-mentioned problems, yet another one of the technical aspects adopted by the present disclosure is to provide a display. The display includes the light-conversion module and a light-emitting module. The light-emitting module is disposed on a light-receiving side of the light-conversion module. The light-emitting module includes a circuit substrate and a plurality of light-emitting elements. The plurality of light-emitting elements are disposed on the circuit substrate.

Therefore, in the light-conversion module, the method for manufacturing the light-conversion module, and the display provided by the present disclosure, by virtue of “the inorganic blocking wall structure having a plurality of through holes,” “the plurality of through holes respectively corresponding to the first sub-pixel regions, the second sub-pixel regions and the third sub-pixel regions,” “a plurality of color filters being respectively disposed at bottom portions of the plurality of through holes,” and “an upper surface of the inorganic blocking wall structure being higher than an upper surface of each of the plurality of color filters,” the height of the inorganic blocking wall structure in the light-conversion module provides an improved blocking effect, thereby increasing a contrast of the display.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic diagram of a display according to one embodiment of the present disclosure;

FIG. 2 is another schematic diagram of the display according to one embodiment of the present disclosure;

FIG. 3 is a schematic cross-sectional view taken along cross-section line II-II of FIG. 2;

FIG. 4 is a flowchart of manufacturing processes of a light-conversion module according to the present disclosure;

FIG. 5 is a schematic cross-sectional view of forming through holes according to one embodiment of the present disclosure;

FIG. 6 is a schematic cross-sectional view of forming a color filter according to one embodiment of the present disclosure;

FIG. 7 is a schematic cross-sectional view of forming a first light-absorbing layer according to one embodiment of the present disclosure;

FIG. 8 is a schematic cross-sectional view of forming a pixel layer according to one embodiment of the present disclosure;

FIG. 9 is a schematic cross-sectional view of thinning a substrate according to one embodiment of the present disclosure; and

FIG. 10 is a schematic cross-sectional view of a hole-forming process performed after the process of thinning the substrate according to one embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

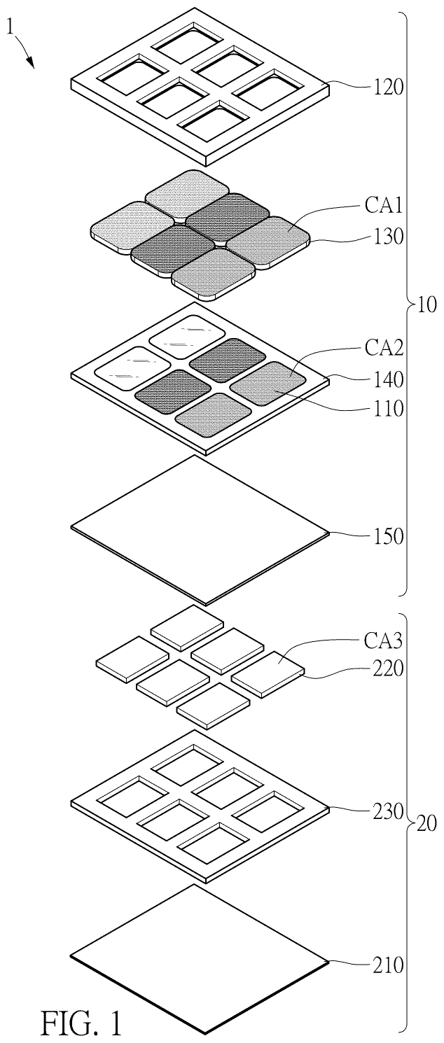

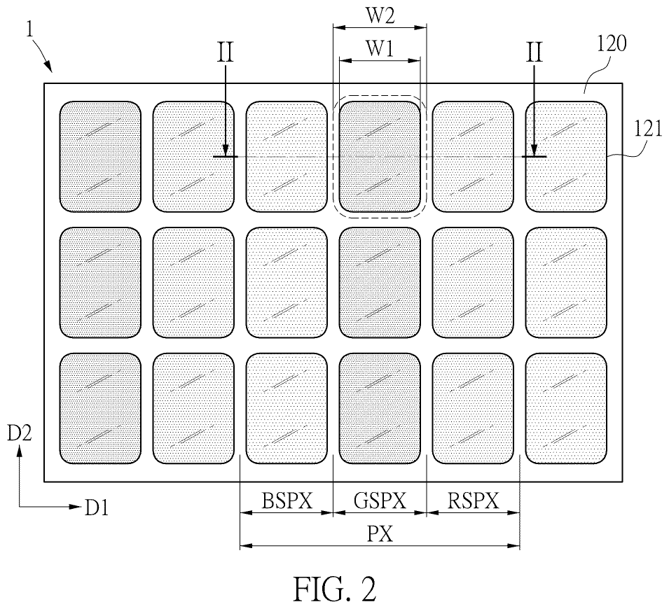

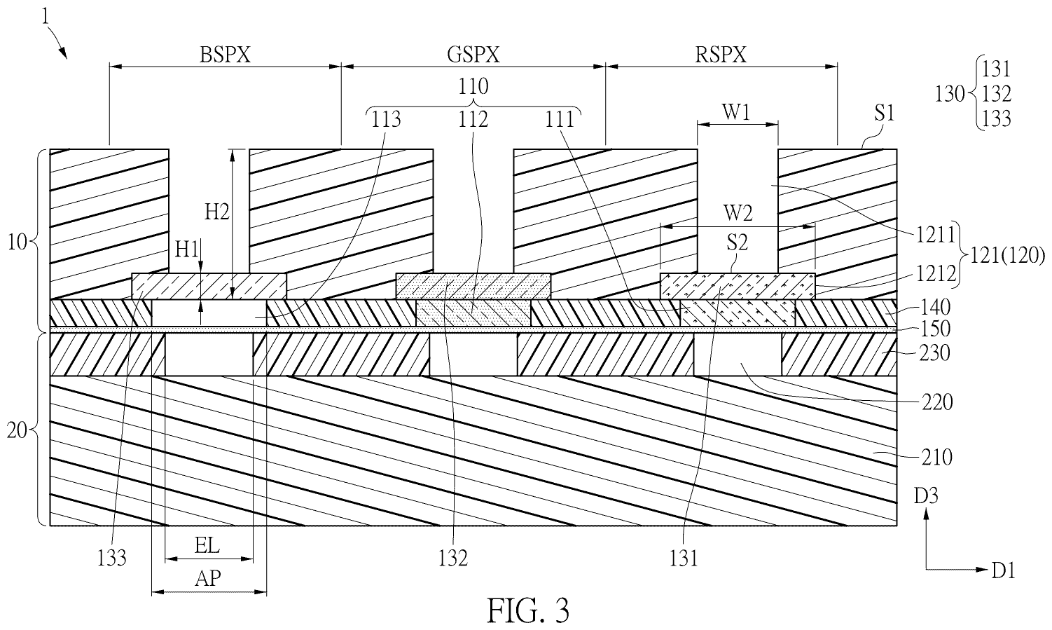

FIG. 1 is a schematic diagram of a display according to one embodiment of the present disclosure. FIG. 2 is another schematic diagram of the display according to one embodiment of the present disclosure. FIG. 3 is a schematic cross-sectional view taken along cross-section line II-II of FIG. 2. As shown in FIG. 1 to FIG. 3, a display 1 of the present disclosure includes a light-conversion module 10 and a light-emitting module 20. The light-emitting module 20 is disposed on a light-receiving side of the light-conversion module 10. The light-conversion module 10 has a plurality of pixel regions PX and an inorganic blocking wall structure 120. Each of the pixel regions PX includes a first sub-pixel region RSPX, a second sub-pixel region GSPX, and a third sub-pixel region BSPX. In this embodiment, the first sub-pixel region RSPX is a red sub-pixel region, the second sub-pixel region GSPX is a green sub-pixel region, and the third sub-pixel region BSPX is a blue sub-pixel region. The display 1 has a plurality of pixel regions PX arranged in an array, and each of the pixel regions PX includes sub-pixel regions having different colors. The pixel region PX in this embodiment has three sub-pixel regions of red, blue, and green colors. However, the pixel region of the present disclosure can also have four colors of red, blue, green, and white; that is, the pixel region has four sub-pixel regions, and colors within a pixel region is not particularly limited in the present disclosure.

The inorganic blocking wall structure 120 surrounds each of the sub-pixel regions and defines a plurality of through holes 121, and in the embodiments of the present disclosure, the through holes 121 have multiple different widths. As shown in FIG. 2 and FIG. 3, on a light-emitting side of the display 1, that is, on a top surface of the inorganic blocking wall structure 120, each of the through holes 121 has a first width W1 in the first direction D1. On a light-receiving side of the inorganic blocking wall structure 120, each of the through holes 121 has a second width W2 in the first direction D1, and the first width W1 is smaller than the second width W2. Specifically, in the plane defined by the first direction D1 and the second direction D2, the through holes in the inorganic blocking wall structure 120 are all in the shape of a rounded rectangle, but a cross-sectional area of each of the through holes 121 at the top surface of the light-emitting side of the inorganic blocking wall structure 120 is smaller than a cross-sectional area of each of the through holes 121 at the light-receiving side of the inorganic blocking wall structure 120. The through holes 121 in this embodiment may include two portions each having different widths. However, in this embodiment of the present disclosure, each of the through holes 121 of the inorganic blocking wall structure 120 may be designed to have two or more different widths according to requirements.

The inorganic blocking wall structure 120 of this embodiment is formed by wafer thinning and drilling processes. The wafer is made of silicon or silicon carbide, and the silicon carbide used in the present disclosure has a new Mohs hardness of 13. After the thinning process, an upper surface of the inorganic blocking wall structure 120 will have grinding traces of the wafer. The height of the inorganic blocking wall structure 120 that is made of grinding a silicon wafer has a better blocking effect to improve the contrast of the display.

As shown in FIG. 3, the light-conversion module 10 includes a pixel layer 110, the inorganic blocking wall structure 120, and a color filter 130. The stacking relationship of each of the elements in the light-conversion module 10 is as follows: the inorganic blocking wall structure 120 is disposed on the pixel layer 110 and includes the plurality of through holes 121, and the color filters 130 are respectively disposed at bottom portions of the plurality of through holes 121. In one embodiment of the present disclosure, since the material of the inorganic blocking wall structure 120 is a silicon wafer, an upper surface S1 of the inorganic blocking wall structure 120 is higher than an upper surface S2 of each of the color filters 130, such that light interference coming from adjacent different colored sub-pixels (i.e., a crosstalk phenomenon) can be effectively blocked.

In addition, the light-emitting module 20 includes a circuit substrate 210 and a plurality of light-emitting elements 220. An adhesive layer 150 is provided at a bottom of the light-conversion module 10, and the adhesive layer 150 bonds the light-conversion module 10 and the light-emitting module 20 to form the display 1. The light-emitting elements 220 in this embodiment are micro light-emitting diodes (micro LEDs), and the type of the light-emitting elements 220 is not specifically limited in the present disclosure.

As shown in FIG. 2 and FIG. 3, in the pixel region PX of this embodiment, adjacent sub-pixel regions along the first direction D1 all exhibit different colors. Therefore, when light emitted by the light-emitting element 220 corresponding to each of the sub-pixel regions sequentially passes through the pixel layer 110 and the color filter 130 corresponding to each of the sub-pixel regions, the inorganic blocking wall structure 120 disposed at the peripheries of each of the sub-pixel regions can effectively block light interference from adjacent sub-pixels of different colors.

Specifically, as shown in FIG. 3, multiple ones of the pixel layers 110 are distributed in multiple pixel regions. Each of the pixel layers 110 includes a first color conversion part 111, a second color conversion part 112, and a light-permeable part 113. The present disclosure does not specifically limit a color of the light emitted by the light-emitting element 220, and the light-emitting element 220 may be, for example, a blue light-emitting diode. For example, in this embodiment, the first sub-pixel region RSPX is a red sub-pixel region, the second sub-pixel region GSPX is a green sub-pixel region, and the third sub-pixel region BSPX is a blue sub-pixel region. The first color conversion part 111 includes a red conversion material, such as red quantum dots. The second color conversion part 112 includes a green conversion material, such as green quantum dots. The red or green quantum dots can change a blue wavelength band of light emitted by the light-emitting module. Specifically, the red quantum dots are excited by received light having blue wavelength bands and convert the blue wavelength bands into red wavelength bands, and the green quantum dots are excited by received light having blue wavelength bands and convert the blue wavelength bands into green wavelength bands. The quantum dot material can effectively improve the luminous efficiency for red and green color lights.

In addition, when the light-emitting element 220 is a blue light-emitting diode, the third sub-pixel region BSPX (i.e., the blue sub-pixel region) does not need to convert a light color, such that the light-permeable part 113 is used in the corresponding pixel layer 110. In this embodiment, a white photoresist having light-scattering particles is used to form the light-permeable portion 113. When the blue light emitted by the light-emitting element 220 passes through the light-permeable part 113, the light-scattering particles in the light-permeable part 113 will disperse the blue light, such that the uniformity of the blue light that is emitted is the same as the uniformity of the red light and green light. However, the light-permeable part 113 may also be empty or made of a transparent material. The present disclosure is not limited to a specific type of the light-permeable part 113.

As shown in FIG. 3, the color filter 130 is provided between the inorganic blocking wall structure 120 and the pixel layer 110. In this embodiment, a red color filter 131 is provided at the first sub-pixel region RSPX, a green color filter 132 is provided at the second sub-pixel region GSPX, and a blue color filter 133 is provided at the third sub-pixel region BSPX. The color filter 130 is disposed on a second portion 1212 of the inorganic blocking wall structure 120, thereby filtering bands of lights having colors other than the desired color to improve the color purity of the emitted light.

In each of the sub-pixel regions, a first light-absorbing layer 140 surrounds the pixel layer 110 to prevent light from penetrating the pixel layer 110 and causing interference. Furthermore, the inorganic blocking wall structure 120 covers above the first light-absorbing layer 140 and partially covers the color filter 130. The first light-absorbing layer 140 surrounds the pixel layer 110 and defines an aperture AP. Each of the through holes 121 in the inorganic blocking wall structure 120 includes a first portion 1211 having a first width W1 and a second portion 1212 having a second width W2. The second portion 1212 is formed below the first portion 1211 and is adjacent to the pixel layer 110. That is, the first portion 1211 of the through hole 121 is connected with the second portion 1212 along a third direction D3 and penetrates the inorganic blocking wall structure 120. In this embodiment, the through holes 121 have different widths in the first direction D1. In each of the through holes 121, the second width W2 of the second portion 1212 is greater than the first width W1 of the first portion 1211. In an existing light-conversion module, a color filter layer and a quantum dot layer have similar sizes and are aligned with each other; when an offset occurs during the aligning of manufacturing machinery and the light-conversion module 10, the color filter layer only partially overlaps with the quantum dot layer, thus causing the display 1 to emit uneven light. In this embodiment, because the width of the pixel layer 110 located under the through hole 121 in the first direction D1 is smaller than the width of the color filter 130, the tolerance of deviation of the alignment between the pixel layer 110 and the color filter 130 becomes greater. In other words, when the pixel layer 110 is formed on the color filter 130 and an offset occurs, since the offset amount is within the tolerance of deviation, the display 1 can still be ensured to emit light that is uniform.

As shown in FIG. 1 to FIG. 3, in this embodiment, the circuit substrate 210 of the light-emitting module 20 has a second light-absorbing layer 230 provided thereon. The second light-absorbing layer 230 surrounds the light-emitting element 220 and defines a light-emitting region EL. As shown in FIG. 1, on the plane defined by the first direction D1 and the second direction D2, since a cross-sectional area CA1 of the color filter 130 is greater than a cross-sectional area CA2 of the pixel layer 110, the cross-sectional area CA1 of the color filter 130 in FIG. 1 is represented by the area enclosed by broken lines. Although a cross-sectional area of the light-emitting region EL is not illustrated in FIG. 1, since the width of the color filter 130 in FIG. 2 is greater than the width of the light-emitting region EL, the cross-sectional area CA1 of the color filter 130 is greater than a cross-sectional area CA3 of the light-emitting region EL. Therefore, when the light-conversion module 10 and the light-emitting module 20 are assembled, the tolerance of deviation of the alignment between the light-conversion module 10 and the light-emitting module 20 becomes greater. In other words, when an offset occurs during the assembly of the light-conversion module 10 and the light-emitting module 20, since an offset amount is within the allowable tolerance of deviation, the light emitted by the light-emitting module 20 can still be ensured to be converted or absorbed by the pixel layer 110.

In this embodiment, the color filter 130 has a height H1, the through hole 121 has a height H2, and the height H1 is substantially less than or equal to a predetermined ratio of the height H2. That is to say, when a lower surface of the color filter 130 is flush with a bottom of the through hole 121, an upper surface of the color filter 130 is not higher than a predetermined ratio of the height H2 of the through hole 121. In this way, the light emitted by the light-emitting module 20 and passing through the upper surface of the color filter 130 can be blocked by the inorganic blocking wall structure 120, thereby further reducing crosstalk between adjacent pixels. In an exemplary embodiment, the height H1 is less than or equal to half of the height H2.

In this embodiment, the first light-absorbing layer 140 and the second light-absorbing layer 230 are both a black matrix. The black matrix includes organic materials, inorganic materials, or metals, and such light-absorbing materials can prevent crosstalk between adjacent pixels.

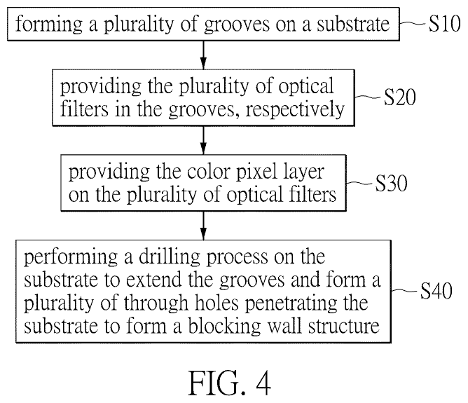

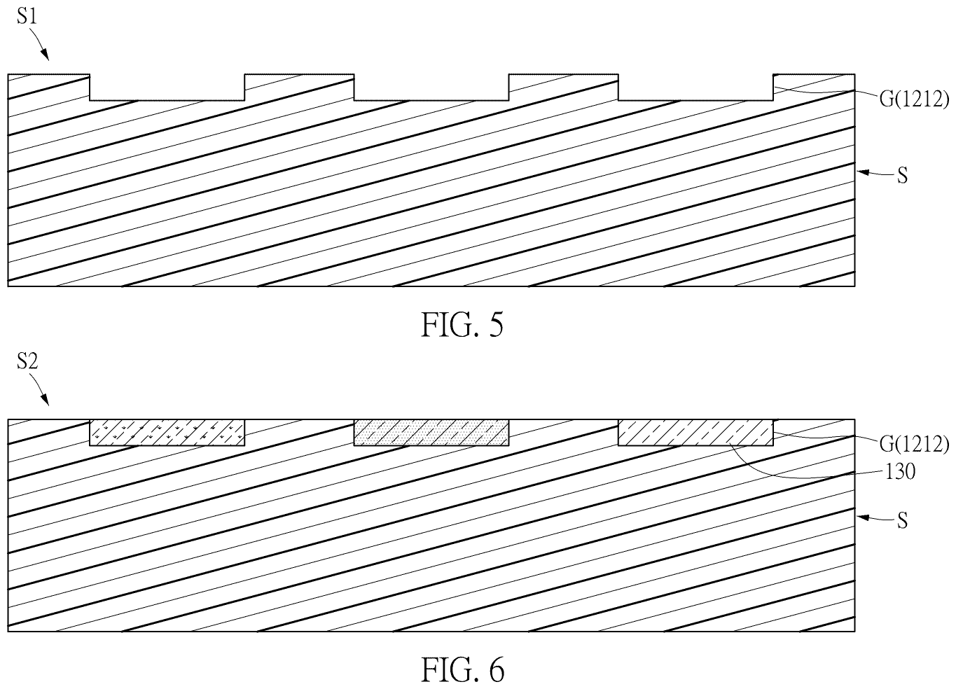

Next, a method for manufacturing the light-conversion module 10 of this embodiment will be described. FIG. 4 is a flowchart of manufacturing processes of a light-conversion module 10 according to the present disclosure. FIG. 5 to FIG. 10 are schematic cross-sectional views of each of the processes according to the embodiments of the present disclosure. Referring to FIG. 4 and FIG. 5 to FIG. 10, one embodiment of the present disclosure provides a method for manufacturing the light-conversion module 10, and the method at least includes the following processes.

Step S10 includes: forming a plurality of trenches G on a substrate S.

FIG. 5 is a schematic view of a process of forming a plurality of through holes according to one embodiment of the present disclosure. As shown in FIG. 4, the trenches G are formed on one side of the substrate S corresponding to the sub-pixel regions. The trenches G that are formed are the second portions 1212 of the through holes 121 of the inorganic blocking wall structure 120 in the light-conversion module 10. In this embodiment, the substrate S can be made of an opaque material, such as silicon or silicon carbide, and the trench G is formed using a yellow-light development process. In this embodiment, a thickness of the substrate S is substantially 700 μm, and an average height of the trench G is substantially 10 μm.

Step S20 includes: providing the plurality of color filters 130 in the trenches G, respectively.

FIG. 6 is a schematic cross-sectional view of forming color filters according to one embodiment of the present disclosure. As shown in FIG. 6, the color filters 130 of different colors are sequentially formed in the trenches G by using a yellow-light development process. The red color filter 131 is formed in the trench G corresponding to the first sub-pixel region RSPX, the green color filter 132 is formed in the trench G corresponding to the second sub-pixel region GSPX, and the blue color filter 133 is formed in the trench G corresponding to the third sub-pixel region BSPX. That is, portions of the color filters 130 respectively corresponding to the first, second, and third sub-pixel regions RSPX, GSPX, and BSPX are red, green, and blue color filters 131, 132, and 133. Moreover, surfaces of the color filters 130 of various colors are flush with the surface of the substrate S; that is, the second portion 1212 of each of the through holes 121 is filled with the color filters 130, and the smooth surface facilitates subsequent film coating process to be performed on the substrate S.

Step S30 includes: providing the pixel layer 110 on the plurality of color filters 130.

FIG. 8 is a schematic cross-sectional view of forming a pixel layer according to one embodiment of the present disclosure. The pixel layer 110 is formed on the color filter 130. The pixel layer 110 includes a plurality of color conversion parts of different colors or light-permeable parts. The present disclosure does not specifically limit the number and color of the sub-pixels and the color conversion parts.

Step S30 further includes step S31.

Step S31 includes: providing the first light-absorbing layer 140 to define the position of the pixel layer 110.

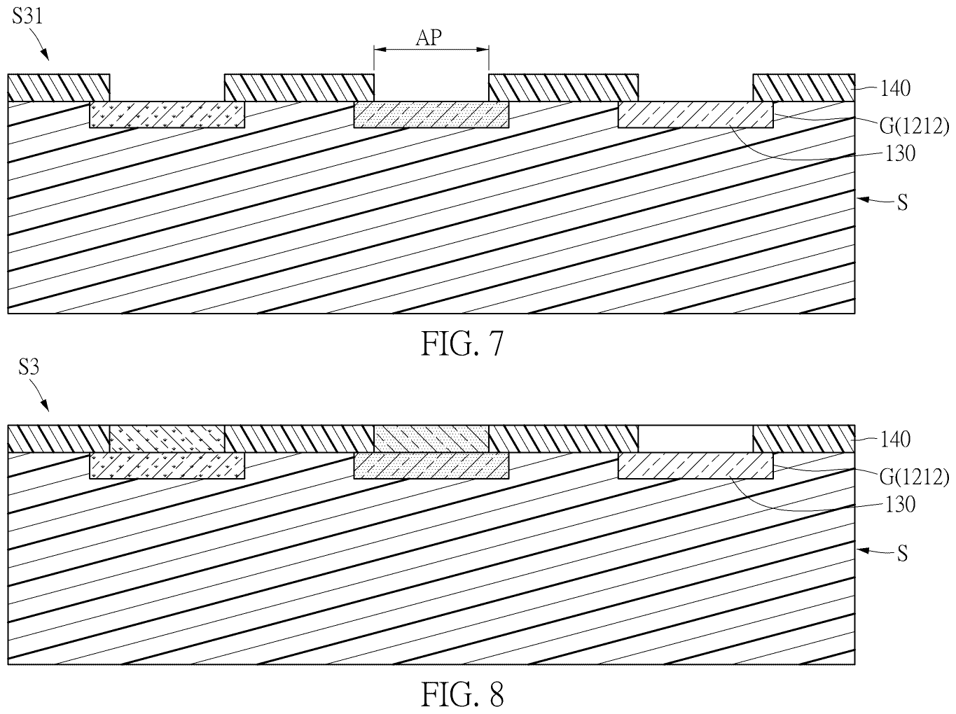

FIG. 7 is a schematic cross-sectional view of forming a first light-absorbing layer according to one embodiment of the present disclosure. As shown in FIG. 7, the first light-absorbing layer 140 is located on the surface of the substrate S and overlaps with the inorganic blocking wall structure 120 and the color filter 130. Specifically, in each of the sub-pixel regions, the first light-absorbing layer 140 may completely cover the inorganic blocking wall structure 120 but only partially cover the color filter 130. In addition, a part of the first light-absorbing layer 140 that does not cover the color filter 130 is defined as the aperture AP. The first light-absorbing layer 140 is formed using a yellow-light development process, and the first light-absorbing layer 140 can prevent crosstalk between adjacent pixels. Moreover, in this embodiment, the thickness of the pixel layer 110 and the first light-absorbing layer 140 are the same, and are approximately in the range of from 5 μm to 10 μm. Therefore, the surface of the light-conversion module 10 is flat, thereby facilitating the combination of the light-conversion module 10 with the light-emitting module in subsequent processes.

Step S40 includes: performing a hole-forming process on the substrate S to extend the trenches G and form a plurality of through holes penetrating the substrate to form an inorganic blocking wall structure 120.

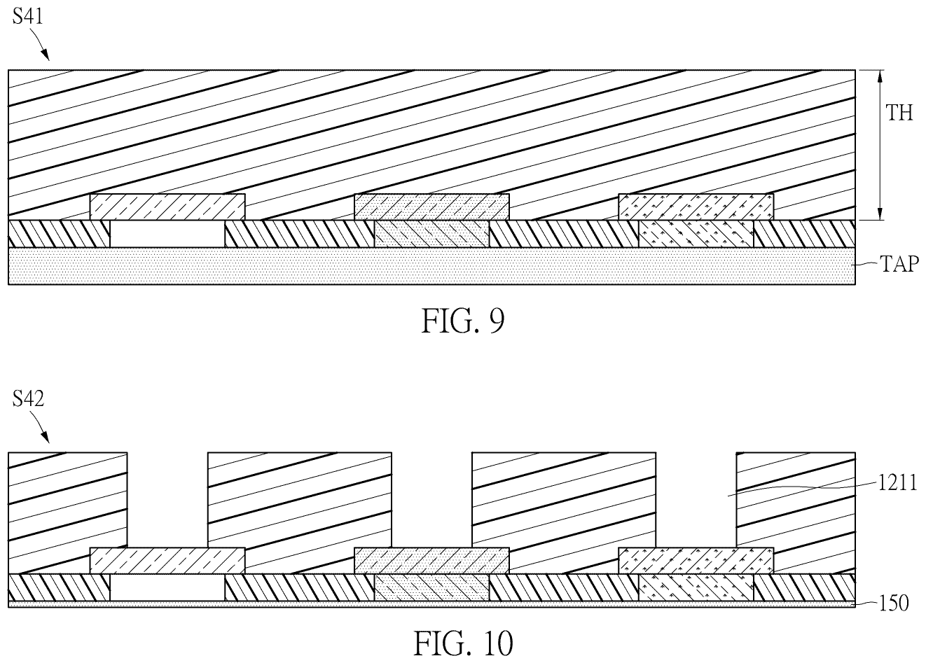

Step S40 further includes step S41 and step S42. Step S41 is shown in FIG. 8, and step S42 is shown in FIG. 9.

Step S41 includes: performing a thinning process on the substrate S, and grinding the substrate S to a predetermined thickness.

FIG. 9 is a schematic cross-sectional view of thinning a substrate according to one embodiment of the present disclosure. As shown in FIG. 9, a protective layer TAP is first attached to the surface of the substrate S having the pixel layer 110. The protective layer TAP is a back grinding tape (BG tape), and the back grinding tape has strong resistance to strong acids and alkali solutions in the etching process and can protect the components of the light-conversion module 10 from being damaged by the strong acids and alkali solutions. Then, the substrate S with the back grinding tape attached is transferred to grinding machinery, and another surface of the substrate S without any components disposed thereon is grinded until the substrate S reaches a predetermined thickness TH (e.g., the predetermined thickness TH is within a range from 50 μm to 200 μm). As shown in FIG. 8, the thickness TH of the substrate S after grinding is reduced. In this embodiment, the thickness TH of the substrate S is reduced from 700 μm to only 50 μm. However, the above-mentioned embodiment is only one example, and the thickness of the substrate S is not particularly limited in the present disclosure. The method for manufacturing in this embodiment adopts wafer grinding, that is, the thickness TH of the substrate S decreases as the external force of grinding is increased. Since the supporting force of the substrate S will become poor if the thickness TH of the substrate S is too thin, the thickness TH of the substrate S has a minimum limit. Furthermore, because the thickness of the inorganic blocking wall structure 120 is equal to the thickness TH of the ground substrate S, a minimum of the thickness of the inorganic blocking wall structure 120 formed by wafer grinding is limited. The thickness TH of the inorganic blocking wall structure 120 can be designed according to requirements in the present disclosure, and a maximum of the thickness of the inorganic blocking wall structure 120 formed by the method for manufacturing the light-conversion module in the present disclosure is not limited.

Step S42 includes: performing a hole-forming process on the substrate S to extend the through holes 121 and form the inorganic blocking wall structure 120.

FIG. 10 is a schematic cross-sectional view of a hole-forming process performed after the process of thinning the substrate S according to one embodiment of the present disclosure. First, a photoresist is coated on the surface of the substrate S that does not have any components disposed thereon, and then patterns are formed on the photoresist by exposure and development. A portion of the surface of the substrate S that is not coated with the photoresist defines the first width W1 of the through hole 121 in the inorganic blocking wall structure 120. Then, the substrate S is etched, and the etching process terminates at the upper surface of the color filter 130 in the trench G of the substrate S. At this time, the photoresist is removed, and then the BG tape is irradiated with ultraviolet light to facilitate peeling of the BG tape from the substrate S. Next, as shown in FIG. 10, the adhesive layer 150 is formed on the surface of the substrate S having components disposed thereon, and the adhesive layer 150 is used to adhere the light-emitting module 20 and the light-conversion module 10.

### Beneficial Effects of the Embodiments

One of the beneficial effects of the present disclosure is that, in the light-conversion module, the method for manufacturing the light-conversion module, and the display provided by the present disclosure, by virtue of “the inorganic blocking wall structure having a plurality of through holes,” “the plurality of through holes respectively corresponding to the first sub-pixel regions, the second sub-pixel regions and the third sub-pixel regions,” “a plurality of color filters being respectively disposed at bottom portions of the plurality of through holes,” and “an upper surface of the inorganic blocking wall structure being higher than an upper surface of each of the plurality of color filters,” the height of the inorganic blocking wall structure in the light-conversion module provides an improved blocking effect, thereby increasing a contrast of the display.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A light-conversion module suitable for a light-emitting module having a plurality of light-emitting elements, the light-conversion module having a plurality pixel regions each having a first sub-pixel region, a second sub-pixel region, and a third sub-pixel region, the light-conversion module comprising:
a pixel layer including a plurality of first color conversion parts respectively corresponding to the first sub-pixel regions, a plurality of second color conversion parts respectively corresponding to the second sub-pixel regions, and a plurality of light-permeable parts respectively corresponding to the third sub-pixel regions;
an inorganic blocking wall structure disposed on the pixel layer and having a plurality of through holes, wherein the plurality of through holes respectively correspond to the first sub-pixel regions, the second sub-pixel regions and the third sub-pixel regions; and
a plurality of color filters respectively disposed in the plurality of through holes, and each of the plurality of color filters is located at a bottom portion of a corresponding one of the plurality of through holes;
wherein an upper surface of the inorganic blocking wall structure is higher than an upper surface of each of the plurality of color filters.

2. The light-conversion module according to claim 1, wherein a width of each of the color filters in a first direction is greater than a width of a corresponding one of the first color conversion parts, the second color conversion parts, or the light-permeable parts in the first direction.

3. The light-conversion module according to claim 1, wherein the upper surface of each of the color filters is not higher than half of a height of the through holes.

4. The light-conversion module according to claim 1, wherein each of the through holes includes:
a first portion having a first width in a first direction; and
a second portion arranged below the first portion and adjacent to the pixel layer for accommodating a corresponding one of the color filters, wherein the second portion has a second width in the first direction greater than the first width.

5. The light-conversion module according to claim 4, further comprising a first light-absorbing layer disposed in peripheries of the first color conversion parts, the second color conversion parts, and the light-permeable parts to define corresponding ones of a plurality of apertures.

6. The light-conversion module according to claim 5, wherein the second width of the second portion in the first direction is greater than or equal to a width of a corresponding one of the apertures in the first direction.

7. The light-conversion module according to claim 1, further comprising an adhesive layer disposed below the pixel layer.

8. The light-conversion module according to claim 1, wherein a portion of the color filters corresponding to the first sub-pixel regions are red color filters, a portion of the color filters corresponding to the second sub-pixel regions are green color filters, and a portion of the color filters corresponding to the third sub-pixel regions are blue color filters.

9. The light-conversion module according to claim 1, wherein an upper surface of the inorganic blocking wall structure has grinding traces.

10. The light-conversion module according to claim 1, wherein the inorganic blocking wall structure is made of silicon or silicon carbide.

11. A display, comprising:
the light-conversion module as claimed in claim 1; and
a light-emitting module disposed on a light-receiving side of the light-conversion module,
wherein the light-emitting module includes:
a circuit substrate; and
a plurality of light-emitting elements disposed on the circuit substrate.

12. The display according to claim 11, wherein the light-emitting module further includes a second light-absorbing layer disposed in peripheries of the light-emitting elements to define corresponding ones of a plurality of light-emitting regions; wherein a width of each of the first color conversion parts, the second color conversion parts, and the light-permeable parts in the first direction is greater than or equal to a width of each of the light-emitting regions in the first direction.

13. A method for manufacturing a light-conversion module, comprising following processes:
forming a plurality of trenches on a substrate;
providing a plurality of color filters in the trenches, respectively;
providing a pixel layer on the plurality of color filters; and
performing a hole-forming process on the substrate to extend the trenches and form a plurality of through holes penetrating the substrate, so as to form an inorganic blocking wall structure;
wherein an upper surface of the inorganic blocking wall structure is higher than an upper surface of each of the plurality of color filters.

14. The method according to claim 13, wherein a width of each of the color filters in a first direction is greater than a width of a corresponding one of first color conversion parts, second color conversion parts, or light-permeable parts in the first direction.

15. The method according to claim 13, wherein the upper surface of each of the color filters is not higher than half of a height of the through holes.

16. The method according to claim 13, wherein each of the through holes includes:
a first portion having a first width in a first direction; and
a second portion arranged below the first portion and adjacent to the pixel layer for accommodating the corresponding color filters, wherein the second portion has a second width in the first direction greater than the first width.

17. The method according to claim 16, further comprising: providing a first light-absorbing layer disposed in peripheries of the first color conversion parts, the second color conversion parts, and the light-permeable parts to define corresponding ones of a plurality of apertures;
wherein the second width of the second portion in the first direction is greater than or equal to a width of a corresponding one of the plurality of apertures in the first direction.

18. The method according to claim 13, wherein, after the process of forming the pixel layer on the substrate, the method further comprises: performing a thinning process on the substrate, including:
providing a protective layer on a light-receiving side of the substrate; and
grinding the substrate to a predetermined thickness;
wherein a thickness of each of the color filters does not exceed half of the predetermined thickness.

19. The method according to claim 13, further comprising: disposing an adhesive layer below the pixel layer.

20. The method according to claim 13, wherein a width of each of the color filters in a first direction is greater than a width of a corresponding one of the first color conversion parts, the second color conversion parts, or the light-permeable parts in the first direction.
